(19) United States
(12) Patent Application Publication
(10) Pub. No.: US 2025/0132179 A1
(43) Pub. Date: Apr. 24, 2025

(54) VIRTUAL METROLOGY FOR ENHANCED WINDOW TEMPERATURE CONTROL

(71) Applicant: Applied Materials, Inc., Santa Clara, CA (US)

(72) Inventors: Ala MORADIAN, Sunnyvale, CA (US); Ramakrishnan BASHYAM, San Jose, CA (US)

(21) Appl. No.: 18/383,411

(22) Filed: Oct. 24, 2023

(51) Int. Cl. H01L 21/67; H01L 21/66

(52) U.S. Cl. CPC H01L 21/67248; H01L 22/12

(57) ABSTRACT

Embodiments of the disclosure relate to a substrate processing system with improved thermal management. The substrate processing system utilizes a pyrometer for temperature measurement on the outer surface of a chamber body, and a controller to adjust operations based on estimated temperatures at various locations on the inner surface of a chamber body. The system employs a digital twin model, potentially physics-based, data-based, or a hybrid, to simulate process runs and generate temperature mappings inside the chamber body. The chamber structure features a chamber body made from high IR transmission materials and includes a chamber conditioning assembly with variable speed blowers and mechanical flow modulators. The associated method manipulates the system with the digital twin model and the chamber conditioning assembly for enhanced temperature control. Furthermore, an apparatus is presented, equipped with mechanical flow modulators directing air flows for effective thermal regulation, migrating unwanted window coating.

### BACKGROUND

### Field

Embodiments of the present disclosure generally relate to systems, methods, and apparatus for enhanced temperature control of hardware components in a process chamber to eliminate unwanted coating on the surface of the hardware components such as a top plate in an epitaxy or chemical vapor deposition (CVD) chamber in semiconductor manufacturing.

### Description of the Related Art

An epitaxy or chemical vapor deposition (CVD) process in semiconductor manufacturing involves high temperature processing in an enclosed processing region. The processing region is enclosed from both top and bottom by clear quartz windows, referred to as upper and lower windows. A common challenge in such processes is window coating, which refers to unwanted deposition of materials on the transparent chamber surface. Such unwanted window coatings can have serious adverse effect on the process results. One impact is that excessive coating can fall off and contribute to particle contamination on the thin film being deposited on a substrate being processed. Another potential adverse impact is that the coating will gradually diminish the transparency of the window to infrared (IR) and in turn increases the amount of the energy that is absorbed by the window itself. In turn, the window temperature can keep on increasing in the area with more coating. If the temperature of the window in one area exceeds a threshold (e.g., 900° C.) the quartz could permanently lose its transparency.

A system, method, and apparatus for monitoring, predicting, and control of temperature in the processing region, in particular the inner surface of the window (surface facing the process gases), is needed to eliminate unwanted window coating.

### SUMMARY

Embodiments of the present disclosure generally relate to system, method, and apparatus for enhanced thermal management in a substrate processing system.

In one aspect, a substrate processing system is provided. The substrate processing system includes a chamber body at least partially enclosing a substrate processing region. The system also includes a pyrometer to take a temperature measurement of a first location of the chamber body. The system also includes a controller configured to: estimate temperature at one or more second locations of the chamber body based on the temperature measurement at the first location, and adjust an operation of the substrate processing system based on the estimated temperature at the one or more second locations. The system also includes a digital twin model designed to emulate components and processes of the chamber body. The digital twin model is a physics-based model, a data-based model, or a hybrid model that incorporates both physics-based and data-based modeling approaches.

In another aspect, embodiments of the present disclosure provide a method for operating a substrate processing chamber. The method includes taking a temperature measurement at a first location of a chamber body that at least partially encloses a substrate processing region. The method also includes estimating temperature at one or more second locations of the chamber body based on the temperature measurement. The method also includes adjusting an operation of the substrate processing chamber based on the estimated temperature at the one or more second locations.

In another aspect, a chamber conditioning assembly is provided. The chamber conditioning assembly includes one or more variable speed blowers configured to supply an air flow to a chamber body. The assembly also includes a first mechanical flow configured to direct a first air flow stream towards a central region of the chamber body, and a second mechanical flow modulator configured to direct a second air flow stream towards a periphery region of the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 depicts a system architecture, according to embodiments of the present disclosure.

FIG. 2 illustrates a system for window temperature control, according to embodiments of the present disclosure.

FIG. 3A illustrates a method for window temperature control, according to embodiments of the present disclosure.

FIG. 3B illustrates another method for window temperature control, according to embodiments of the present disclosure.

FIG. 4 is a schematic, cross-sectional, side view of a process chamber, according to embodiments of the present disclosure.

FIG. 5 is a schematic, cross-sectional, side view of a chamber conditioning assembly, according to embodiments of the present disclosure.

FIG. 6 is a schematic, cross-sectional, side view of a central flow modulator, according to embodiments of the present disclosure.

FIG. 7A is a schematic, isometric, view of a periphery flow modulator, according to embodiments of the present disclosure.

FIG. 7B illustrates an operation of the periphery flow modulator, according to embodiments of the present disclosure.

FIG. 8 illustrates dynamic air flows in the chamber conditioning assembly, according to embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to systems, apparatus, and methods for monitoring, predicting, and control of the surface temperature of a semiconductor process chamber.

### Exemplary System Architecture

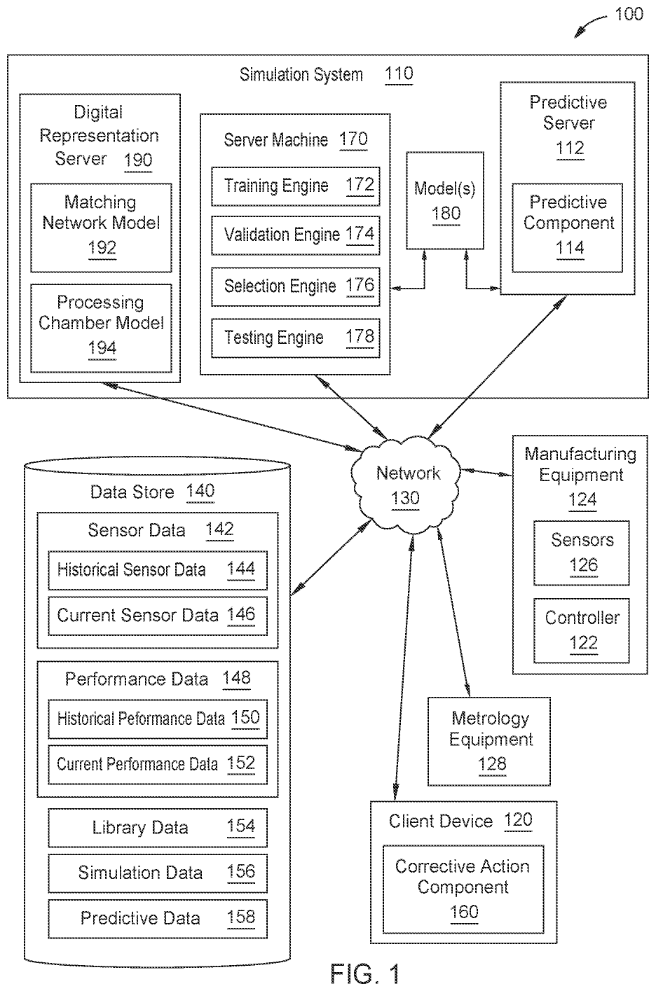

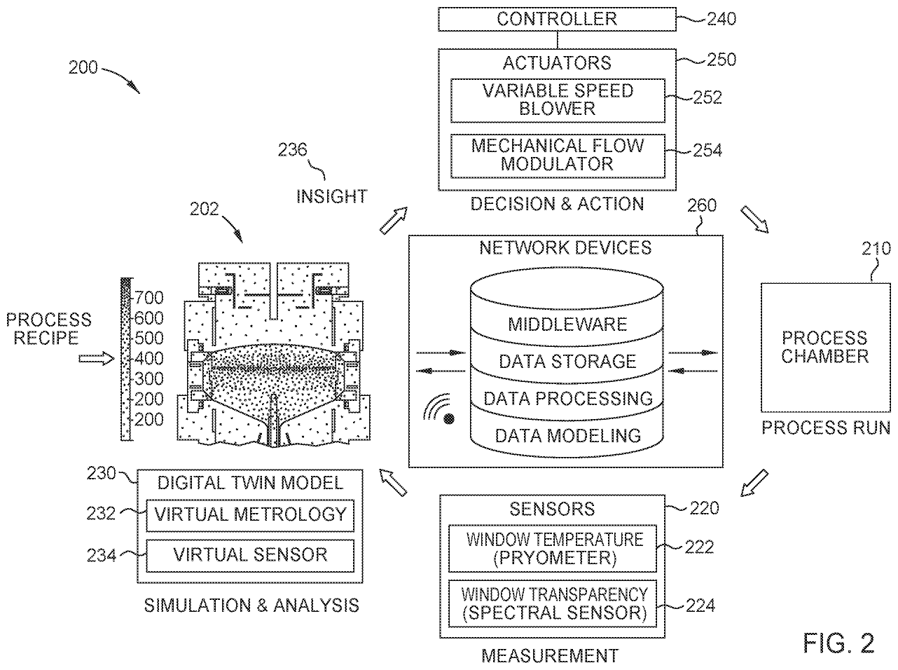

FIG. 1 depicts a system architecture, according to embodiments of the present disclosure. In some embodiments, the system architecture 100 may be included as part of a substrate processing system, such as system 200 of FIG. 2. The system architecture 100 includes a simulation system 110, a client device 120, manufacturing equipment 124, metrology equipment 128, and a data store 140. The simulation system 110 may include a digital representation server 190, a server machine 170, one or more digital twin models 180, and a predictive server 112. In various embodiments, the system architecture 100 may include fewer or additional components than those depicted in the exemplary figure.

The manufacturing equipment 124 may include sensors 126 configured to capture data for a substrate being processed in the manufacturing system, and a controller 122. In some embodiments, the manufacturing equipment 124 and sensors 126 may be part of a sensor system that includes a sensor server (e.g., field service server (FSS) at a manufacturing facility) and sensor identifier reader (e.g., front opening unified pod (FOUP) radio frequency identification (RFID) reader for sensor system). In some embodiments, metrology equipment 128 may be part of a metrology system that includes a metrology server (e.g., a metrology database, metrology folders, etc.) and metrology identifier reader (e.g., FOUP RFID reader for metrology system).

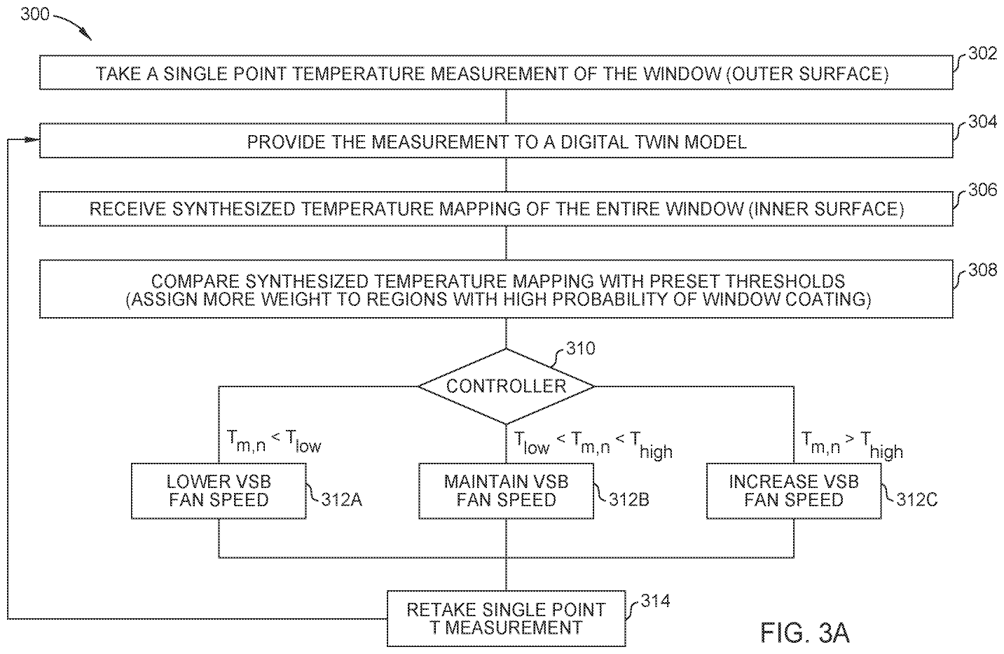

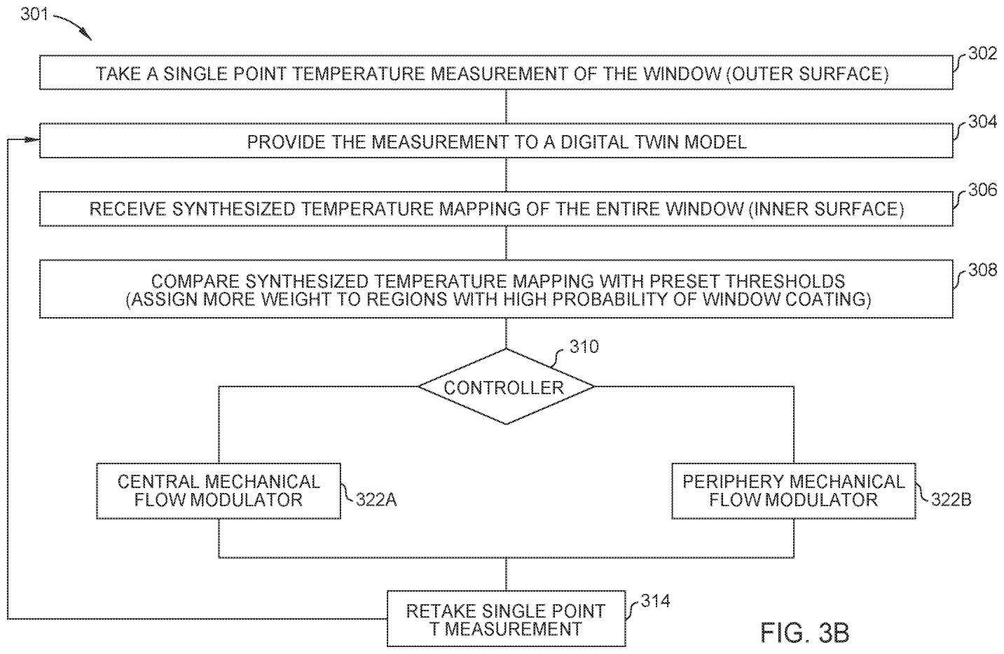

Manufacturing equipment 124 may produce products following a recipe or performing runs over a period of time via the controller 122. While there may be multiple controllers for different parts of manufacturing equipment 124, a generic controller 122 is depicted in the exemplary figure for simplicity. Manufacturing equipment 124 may include a substrate measurement subsystem that includes one or more sensors 126 configured to generate spectral data and/or positional data for a substrate embedded within the substrate measurement subsystem. Sensors 126 that are configured to generate spectral data (herein referred to as spectra sensing components) may include reflectometry sensors, ellipsometry sensors, thermal spectra sensors, capacitive sensors, and so forth. In some embodiments, spectra sensing components may be included within the substrate measurement subsystem or another portion of the manufacturing system. One or more sensors 126 (e.g., eddy current sensors, etc.) may also be configured to generate non-spectral data for the substrate. Further details regarding the manufacturing equipment 124 and the substrate measurement subsystem are provided with respect to FIG. 2 and FIG. 3.

In some embodiments, sensors 126 may provide sensor data associated with the manufacturing equipment 124, and provide inputs to the simulation system 110, and/or a controller of the manufacturing equipment 124. Sensor data may include a value of one or more of temperature (e.g., heater temperature, gas temperature, and/or ambient temperature), spacing (SP), pressure, high frequency radio frequency (HFRF), voltage of electrostatic chuck (ESC), electrical current, flow rate of one or more substances present in manufacturing equipment, power, voltage, etc. Sensor data may be associated with or indicative of manufacturing parameters such as hardware parameters, including settings or components (e.g., size, type, etc.) of the manufacturing equipment 124, or process parameters of the manufacturing equipment 124. The sensor data may be provided while the manufacturing equipment 124 is performing manufacturing processes (e.g., equipment readings when processing products). The sensor data 142 may be different for each substrate.

The metrology equipment 128 may provide metrology data associated with substrates (e.g., wafers, etc.) processed by the manufacturing equipment 124. The metrology data may include a value of one or more of film property data (e.g., wafer spatial film properties), dimensions (e.g., thickness, height, etc.), dielectric constant, dopant concentration, density, defects, etc. In some embodiments, the metrology data may further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data may be of a finished or semi-finished product. The metrology data may be different for each substrate.

The metrology equipment 128 may include on-tool metrology and off-tool metrology. On-tool metrology can include measurements performed on the devices themselves within a die or on test structures having features similar to the devices. Depending on the measurement techniques used, the test structures may include, but are not limited to, structures similar to logic or memory devices that are on the wafers. Off-tool metrology may include in-line metrology (e.g., e-beam inspection and metrology). “In-line metrology” broadly encompasses measurements that may be performed outside of a process chamber, but without having to take the wafer out of the production line. Off-tool metrology may also include data available from any additional non-inline or off-line metrology, such as TEM, previously performed on a similar set of devices.

The client device 120 may include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. In some embodiments, the metrology data may be received from the client device 120. Client device 120 may display a graphical user interface (GUI), where the GUI enables the user to provide, as input, metrology measurement values for substrates processed at the manufacturing system. The client device 120 may also include augmented reality (AR), virtual reality (VR), or mixed reality (MR) devices.

The data store 140 may be a memory (e.g., random access memory), a drive (e.g., a hard drive, a flash drive), a database system, or another type of component or device capable of storing data. Data store 140 may include multiple storage components (e.g., multiple drives or multiple databases) that may span multiple computing devices (e.g., multiple server computers). The data store 140 may include sensor data 142, performance data 148, library data 154, simulation data 156, and predictive data 158. Sensor data 142 may include historical sensor data 144 and current sensor data 146.

The performance data 148 may include historical performance data 150 and current performance data 152. The historical sensor data 144 and historical performance data 150 may be historical data, associated with previous manufacturing runs. The current sensor data 146 may be data associated with a presently ongoing manufacturing run for which simulation data 156 and predictive data 158 are to be generated (e.g., for performing corrective actions). The current performance data 152 may also be for a presently ongoing manufacturing run, and may be used for calibrating or updating a previously established digital twin model.

The data store 140 may store data associated with processing a substrate at manufacturing equipment 124. For example, the data store 140 may store data collected by the sensors 126 at the manufacturing equipment 124 before, during, or after a substrate process (referred to as process data).

The performance data 148 may include data associated with the manufacturing equipment 124 and/or products produced by the manufacturing equipment 124. In some embodiments, the performance data 148 may include an indication of a lifetime of a component of manufacturing equipment 124 (e.g., time of failure), manufacturing parameters of manufacturing equipment 124, maintenance of manufacturing equipment 124, energy usage of a component of manufacturing equipment 124, variance in components (e.g., of same part number) of manufacturing equipment 124, or the like.

The performance data 148 may include an indication of variance in components (e.g., of the same type, of the same part number) of the manufacturing equipment 124. The performance data 148 may indicate if the variance (e.g., jitter, slope, peak, etc.) contributes to product-to-product variation. The performance data 148 may indicate if a variance provides an improved wafer. The performance data 148 may be associated with a quality of products produced by the manufacturing equipment 124. The metrology equipment 128 may provide performance data 148 (e.g., property data of wafers, yield, metrology data) associated with products (e.g., processed wafers) produced by the manufacturing equipment 124. The performance data 148 may include a value of one or more of film property data (e.g., wafer spatial film properties), dimensions (e.g., thickness, height, etc.), dielectric constant, dopant concentration, density, defects, etc. The performance data 148 may be of a finished or semi-finished product. The performance data 148 may be different for each product (e.g., each processed wafer). The performance data 148 may indicate whether a product meets a threshold quality (e.g., defective, not defective, etc.). The performance data 148 may indicate a cause of not meeting a threshold quality. In some embodiments, the performance data 148 includes historical performance data 150, which corresponds to historical property data of products. The sensor data 142, performance data 148, and library data 154 may be used for supervised and/or unsupervised machine learning.

Process data can refer to historical process data (e.g., process data generated for a previous substrate processed at the manufacturing system) and/or current process data (e.g., process data generated for a current substrate processed at the manufacturing system). Data store may also store spectral data or nonspectral data associated with a portion of a substrate processed at manufacturing equipment 124. Spectral data may include historical spectral data and/or current spectral data. Current process data and/or current spectral data may be data for which predictive data is generated. In some embodiments, data store may store metrology data including historical metrology data (e.g., metrology measurement values for a prior substrate processed at the manufacturing system).

The data store 140 may also store contextual data associated with one or more substrates processed at the manufacturing system. Contextual data can include a recipe name, recipe step number, preventive maintenance indicator, operator, etc. In some embodiments, contextual data can also include an indication of a difference between two or more process recipes or process steps. For example, a first process recipe can include an operation including setting an internal temperature of a process chamber to 100° C. A second process recipe can include a corresponding operation including setting the internal temperature of the process chamber to 110° C. Contextual data can include an indication of a difference of the internal temperature of the process chamber between the first process recipe and the second process recipe.

The simulation system 110 may include digital representation server 190, server machine 170, and predictive server 112. The predictive server 112, digital representation server 190, and server machine 170 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc. In some implementations, the simulation system 110 may also include computing clouds, and edge computing devices.

The digital representation server 190 stores a digital representation model, such as the digital twin model 180. The digital representation server 190 may include a matching network model 192 and a process chamber model 194. The matching network model 192 may be associated with the physical elements and the dynamics of the matching network, and may include information such as target reference data or profiles, and threshold values for matching of simulations to target reference profiles. The process chamber model 194 may be associated with the physical elements and the dynamics of the process chamber.

In some embodiments, the digital representation server 190 may generate simulation data 156. Simulation data 156 may include data used to determine how the manufacturing equipment 124 would perform based on current or simulated parameters. The simulation data 156 may further include predicted property data of the digital model of the manufacturing equipment 124 (e.g., of products to be produced or that have been produced). The simulation data 156 may further include predicted metrology data (e.g., virtual metrology data) of the products to be produced or that have been produced. The simulation data 156 may further include an indication of abnormalities (e.g., abnormal products, abnormal components, abnormal manufacturing equipment 124, abnormal energy usage, etc.) and one or more causes of the abnormalities. The simulation data 156 may further include an indication of an end of life of a component of manufacturing equipment 124. The simulation data 156 may be all encompassing, covering any mechanical and electrical aspect of the manufacturing equipment.

The predictive server 112 may include a predictive component 114. In some embodiments, the predictive component 114 may receive simulation data 156 and current performance data 152 (e.g., process chamber flow, process chamber pressure, RF power, etc.) and generate output (e.g., predictive data 158) for performing a corrective action associated with the manufacturing equipment 124.

In some embodiments, the predictive component 114 receives simulation data 156 and one or more of current performance data 152 and current sensor data 146, and provides some or all of this data as input to the digital twin model 180. The predictive component 114 obtains output(s) indicative of predictive data 158 from the digital twin model 180. The digital twin model 180 may be a physics-based model, a data-based model, or a hybrid model synthesizing the physics-based model and the data-based model. The digital twin model 180 may include a single model, or multiple models. In some embodiments, the digital twin model 180 may use additional data from the data store 140 (e.g., library data 154, performance data 148, sensor data 142, etc.) or other metrology data.

In some embodiments, the simulation system 110 further includes server machine 170. The server machine 170 may, using a data set generator, generate one or more data sets (e.g., a set of data inputs and a set of target outputs) to train, validate, and/or test the digital twin model 180. In particular, the server machine 170 can include a training engine 172, a validation engine 174, selection engine 176, and/or a testing engine 178. An engine (e.g., training engine 172, a validation engine 174, selection engine 176, and a testing engine 178) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof.

The training engine 172 may be capable of training a digital twin model 180 using one or more sets of features associated with the training set from a data set generator. The training engine 172 may generate multiple digital twin models 180, where each digital twin model 180 corresponds to a distinct set of features of the training set (e.g., sensor data from a distinct set of sensors). The validation engine 174 may be capable of validating a digital twin model 180 using a corresponding set of features of the validation set from data set generator. The validation engine 174 may determine an accuracy of each of the digital twin models 180 based on the corresponding sets of features of the validation set. The validation engine 174 may discard digital twin models 180 that have an accuracy that does not meet a threshold accuracy. In some embodiments, the selection engine 176 may be capable of selecting one or more digital twin models 180 that have an accuracy that meets a threshold accuracy. In some embodiments, the selection engine 176 may be capable of selecting the digital twin model 180 that has the highest accuracy of the digital twin models 180. The testing engine 178 may be capable of testing a digital twin model 180 using a corresponding set of features of a testing set from data set generator. The testing engine 178 may determine a digital twin model 180 that has the highest accuracy of all of the digital twin models based on the testing sets.

The predictive component 114 may provide simulation data 156 and current sensor data 146 to the digital twin model 180 and may run the digital twin model 180 on the input to obtain one or more outputs. The predictive component 114 may be capable of determining (e.g., extracting) predictive data 158 from the output of the digital twin model 180.

For purpose of illustration, rather than limitation, aspects of the disclosure describe the training of one or more digital twin models 180 and inputting simulation data 156 and sensor data 142 into the one or more digital twin models 180 to determine predictive data 158. Predictive component 114 may monitor historical sensor data 144 and/or historical performance data 150. Any of the information described with respect to data from the data store 140 may be monitored or otherwise used in the heuristic or rule-based model.

In some embodiments, the functions of the client device 120, the predictive server 112, the digital representation server 190, and the server machine 170 may be provided by a fewer number of machines. For example, in some embodiments, the digital representation server 190 and the server machine 170 may be integrated into a single machine, while in some other embodiments, the digital representation server 190 and the server machine 170, and the predictive server 112 may be integrated into a single machine. In some embodiments, the client device 120 and the predictive server 112 may be integrated into a single machine.

In general, functions described in one embodiment as being performed by the client device 120, the predictive server 112, the digital representation server 190 and the server machine 170 can also be performed on the predictive server 112 in other embodiments, if appropriate. In addition, the functionality attributed to a particular component can be performed by different or multiple components operating together. For example, in some embodiments, the predictive server 112 may determine the corrective action based on the predictive data 158. In another example, the client device 120 may determine the predictive data 158 based on output from the digital twin model 180.

In addition, the functions of a particular component can be performed by different or multiple components operating together. One or more of the predictive server 112, digital representation server 190 and server machine 170 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

Embodiments of the disclosure may be applied to data quality evaluation, feature enhancement, model evaluation, Virtual Metrology (VM), Predictive Maintenance (PdM), limit optimization, or the like.

Although embodiments of the disclosure are discussed in terms of generating predictive data 158 to perform a corrective action in manufacturing facilities (e.g., semiconductor manufacturing facilities), embodiments may also be generally applied to characterizing and monitoring components. Embodiments may be generally applied to characterizing and monitoring based on different types of data.

The client device 120, the manufacturing equipment 124, the sensors 126, the metrology equipment 128, the predictive server 112, the data store 140, the digital representation server 190, and the server machine 170 may be coupled to each other via a network 130 for generating predictive data 158 to perform corrective actions.

In some embodiments, the network 130 is a public network that provides client device 120 with access to the predictive server 112, the data store 140, and other publically available computing devices. In some embodiments, the network 130 is a private network that provides the client device 120 access to the manufacturing equipment 124, the metrology equipment 128, the data store 140, and other privately available computing devices. The network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

The client device 120 may include a corrective action component 160. The corrective action component 160 may receive user input (e.g., via a Graphical User Interface (GUI) displayed via the client device 120) of an indication associated with the manufacturing equipment 124. In some embodiments, the corrective action component 160 transmits the indication to the simulation system 110, receives output (e.g., predictive data 168) from the simulation system 110, determines a corrective action based on the output, and causes the corrective action to be implemented. In some embodiments, the corrective action component 160 obtains sensor data 142 associated with the manufacturing equipment 124 (e.g., from data store 140, etc.) and provides the sensor data 142 associated with the manufacturing equipment 124 to the simulation system 110. In some embodiments, the corrective action component 160 stores sensor data 142 in the data store 140 and the predictive server 112 retrieves the sensor data 142 from the data store 140.

In some embodiments, the predictive server 112 may store output (e.g., predictive data 168) of the digital twin model 180 in the data store 140 and the client device 120 may retrieve the output from the data store 140. In some embodiments, the corrective action component 160 receives an indication of a corrective action from the simulation system 110 and causes the corrective action to be implemented. Each client device 120 may include an operating system that allows users to generate, view, and/or edit data (e.g., indication associated with manufacturing equipment 124, corrective actions associated with manufacturing equipment 124, etc.).

Performing manufacturing processes that result in defective products can be costly in time, energy, products, components, manufacturing equipment 124, the cost of identifying the defects and discarding the defective product, etc. By inputting sensor data 142 (e.g., manufacturing parameters that are being used or are to be used to manufacture a product), receiving output of predictive data 168, and performing a corrective action based on the predictive data 168, the system architecture 100 can have the technical advantage of avoiding the cost of producing, identifying, and discarding defective products.

Performing manufacturing processes that result in failure of the components of the manufacturing equipment 124 can be costly in downtime, damage to products, damage to equipment, express ordering replacement components, etc. By inputting sensor data 142 (e.g., manufacturing parameters that are being used or are to be used to manufacture a product), receiving output of predictive data 168, and performing corrective action (e.g., predicted operational maintenance, such as replacement, processing, cleaning, etc. of components) based on the predictive data 168, the system architecture 100 can have the technical advantage of avoiding the cost of one or more of component failure, downtime, productivity loss, equipment failure, product scrap, or the like.

Corrective action may be associated with one or more of Computational Process Control (CPC), Statistical Process Control (SPC) (e.g., SPC on electronic components to determine process in control, SPC to predict useful lifespan of components, SPC to compare to a graph of 3-sigma, etc.), Advanced Process Control (APC), model-based process control, preventative operative maintenance, design optimization, updating of manufacturing parameters, feedback control, machine learning modification, or the like. In some embodiments, the corrective action may include adjusting one or more of the controllable variable tuning elements, such as knobs, as discussed in further detail herein.

In some embodiments, the corrective action includes providing an alert (e.g., an alarm to stop or not perform the manufacturing process if the predictive data 168 indicates a predicted abnormality, such as an abnormality of the product, a component, or manufacturing equipment 124). In some embodiments, the corrective action includes providing feedback control (e.g., modifying a manufacturing parameter responsive to the predictive data 168 indicating a predicted abnormality). In some embodiments, the corrective action includes providing machine learning (e.g., modifying one or more manufacturing parameters based on the predictive data 168). In some embodiments, performance of the corrective action includes causing updates to one or more manufacturing parameters.

Manufacturing parameters may include hardware parameters (e.g., replacing components, using certain components, replacing a processing chip, updating firmware, etc.) and/or process parameters (e.g., temperature, pressure, flow rate, electrical current, voltage, gas flow, lift speed, etc.). In some embodiments, the corrective action includes causing preventative operative maintenance (e.g., replace, process, clean, etc. components of the manufacturing equipment 124). In some embodiments, the corrective action includes causing design optimization (e.g., updating manufacturing parameters, manufacturing processes, manufacturing equipment 124, etc. for an optimized product). In some embodiments, the corrective action includes updating a recipe (e.g., manufacturing equipment 124 to be in an idle mode, a sleep mode, a warm-up mode, etc.).

### System and Method for Window Temperature Control

FIG. 2 illustrates a system 200 for window temperature control, according to embodiments of the present disclosure. The system 200 may include a process chamber 210, sensors 220, a digital representation 202 of the process chamber 210, also called a digital twin model 230, comprising a virtual metrology 232 and/or virtual sensor 234 as part of the digital twin model 230, a controller 240, and actuators 250 to respond to the output of the virtual metrology or virtual sensor.

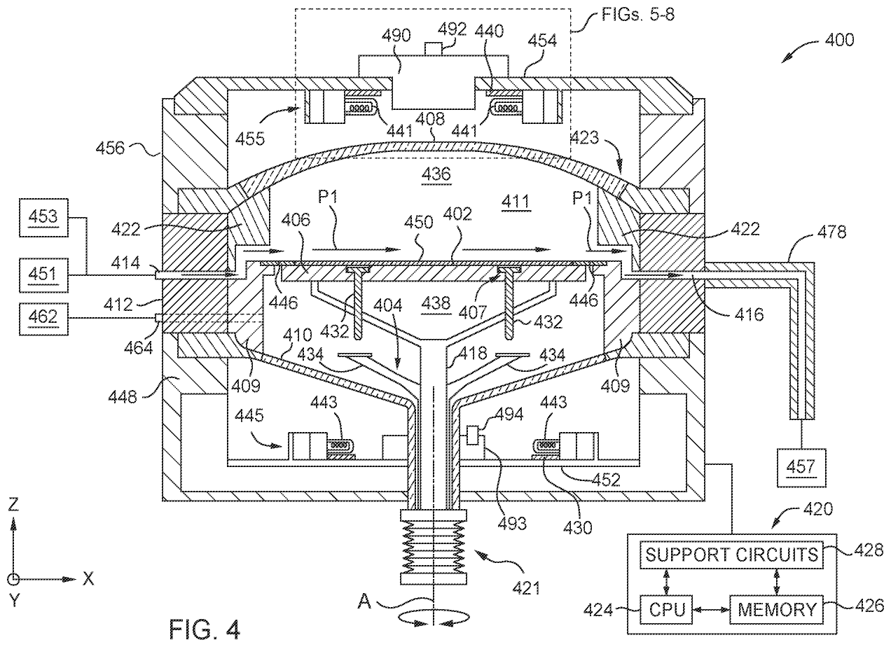

The process chamber 210 is a physical device that is configured to process a substrate. In some embodiments, the process chamber 210 may be an enclosed reactor, a cluster or linear tool comprising one or more interconnected process modules, or a physical device that can be used in combination with a digital twin model 230 as described herein. In some implementations, the process chamber 210 is also called a “physical twin chamber” in the context of a digital twin system. In one application, the process chamber 210 is configured to conduct an epitaxy process. In other applications, the process chamber 210 may be configured to conduct any semiconductor processes, including but not limited to etch, atomic layer deposition (ALD), chemical vapor deposition (CVD), rapid thermal processing or annealing (RTP/RTA). A detailed further description of an example of the process chamber 210 is depicted in and described with respect to FIG. 4.

The sensors 220 conduct measurement of processing status. The sensors 220 measure one or more parameters of interest, such as temperature, pressure, concentration, etc. According to embodiments of the disclosure, the sensors 220 may include one or more pyrometers 222 that takes a single point temperature measurement at an arbitrary location on an upper window 408 and/or a lower window 410 of the process chamber 210, as depicted and described with respect to FIG. 4 herein. The upper window 408 and/or a lower window 410 can be a dome-shaped structure in the present disclosure, but not limited to a particular geometric shape. In some implementations, the upper window 408 and/or a lower window 410 can be two separate transparent pieces. In other implementations, the upper window 408 and/or a lower window 410 can be an upper portion and a lower portion of a monolithic frameless box that is made entirely from transparent materials, such as clear quartz. The single point temperature measurement provides a single data point of outer surface temperature of the upper/lower window. The sensors 220 may also include a spectral sensor 224 that measures window transparency at an arbitrary location on the upper/lower window, and material composition of a coating. The sensors 220 may also include other characteristics of the upper/lower window or substrate in processing.

The digital twin model 230 emulates every component and process of the process chamber 210. The digital twin model 230 encompasses the geometry of the upper/lower window, the arrays of lamps, the rate of air flow, the thickness and material of the quartz windows, and other intricate details. All these components are digitally reproduced with a high degree of fidelity. The digital twin model 230 comprises a virtual metrology 232 and/or virtual sensor 234 as part of the digital twin model 230. Virtual metrology 232 can include time traces of various process variables, such as pressure, temperature, RF power, current, voltage, flow control position, etc. Virtual sensor 234 provides value of a physical parameter estimated or inferred based on a model or sometimes referred to as a digital replica or digital twin of the system. The digital twin model 230 can be a physics-based model, a data-based model, or a hybrid model of the process chamber 210 under different operational states.

The physics-based model uses physics and first principles as well as the actual geometry and physical characteristics of the system to predict temperature distribution on the upper/lower window and in the processing volume of the process chamber 210. The physics based model meticulously simulates the entire physical system, from the geometric details of the upper/lower window and lamp arrays to the complexities of radiative heating mechanisms. Leveraging advanced algorithms derived from thermodynamics, fluid dynamics, and radiation physics, the physical based model offers predictions on temperature distributions and essential operational parameters.

The data-based model emphasizes information gathered directly from the process runs conducted by the process chamber 210, such as an epitaxy or CVD chamber. The model, equipped with sensors, and various data collection apparatuses, amasses vast operational datasets. This accumulated data is subsequently processed through sophisticated algorithms, such as machine learning algorithms, to generate predictions and suggest real-time adjustments.

The hybrid model is a synthesis of the physics-based and data-based models. It employs the foundational algorithms and structures provided by physical principles and refines them using real-time operational data for enhanced accuracy and adaptability. This integrative approach ensures the model is continuously calibrated and updated during the process run cycles.

In some embodiments of the disclosure, the digital twin model 230 receives an input of a process recipe, conducts a virtual processing (simulated process run), and generates an output of temperature mapping inside the process chamber 210. The process recipe may include the size, thickness, and materials of the substrate to be processed, the concentration and flow rate of process gases, the electric power supplied to heat sources, the electric power supplied to variable speed blower (VSB), etc.

The digital twin model 230 also receives an output from the sensors 220, and uses the received data to perform simulation and analysis. Simulation and analysis generates an output of interest, called an insight 236. The Insight 236 may include process critical parameters, emissivity characteristics, thermal uniformity data, process and sensor drift information, substrate digital twin data, and the like. According to embodiments of this disclosure, the insight 236 may include the temperature mapping of the internal surface of the upper/lower window.

The digital twin model 230 may determine the insight 236 automatically and transmit the insight 236 to the process chamber 210 in real-time. The automation of the process and execution of the process in real-time provides many benefits in terms of efficiency and accuracy of controlling and managing the process chamber 210.

Based on process knowledge, the upper and lower windows of the process chamber 210 can be defined in a GUI or backend code into a few regions. When using temperature information from the digital twin model 230, different weights are given to the temperature of one or some of the regions. In one embodiment, there may be a region, for example, near an exhaust, which based on process knowledge, has high probability of coating. The user is able to set a higher priority or weight to the temperature of this region to be used for blower speed control.

The insight 236 generated by the digital twin model 230 may be transmitted, or otherwise provided, to the controller 240 for decision. The controller 240 is a physical device or software program, or a combination thereof, responsible for managing or directing the system 200's behavior to achieve a desired set of outcomes or objectives. According to embodiments of the present disclosure, the controller 240 checks the overall temperature mapping of the upper and lower windows and determines if the temperature at any location exceeds a pre-set higher threshold or is below a pre-set lower threshold. The controller 240 then sends an action command to the actuators 250 to adjust the temperature. The controller 240 can operate in an open-loop format, without feedback, delivering a constant output for a particular input, or in a closed-loop (feedback) format, where the controller 240 continuously adjusts system operations based on discrepancies between the desired and actual outputs.

Embodiments of the controller 240 include a closed-loop controller, an adaptive controller, an intelligent controller, a robust controller, or a stochastic controller. A closed-loop controller, such as a proportional-integral-derivative (PID) controller, compares the output of a system to a desired reference (or set point) and adjusts the input based on this comparison. The main goal is to reduce the error between the system's output and the desired reference. An adaptive control system can adjust its parameters in real-time based on the feedback and other information, allowing it to perform well even in the presence of system uncertainties or changes in the system dynamics. An adaptive control system can adjust its parameters in real-time based on the feedback and other information, allowing it to perform well even in the presence of system uncertainties or changes in the system dynamics. Intelligent controllers often refer to those that incorporate techniques from artificial intelligence, like neural networks, fuzzy logic, or genetic algorithms. These controllers are capable of handling nonlinearities, uncertainties, and other complexities better than traditional control algorithms. Robust control deals with uncertainties in model parameters and unmodeled dynamics. A robust controller ensures that a system's performance remains at a desired level even in the presence of such uncertainties. Stochastic control deals with systems that are subjected to random disturbances or have inherent randomness. Embodiments of the system 200 may include one or a combination of the above controllers 240.

The actuators 250 executes an action command sent by the controller 240. Actions are examples of corrective actions performed concerning the process chamber 210 and the processes performed by the process chamber 210. According to embodiments of the present disclosure, the actuators 250 include at least one or more variable speed blowers 252, which generate an air flow in the process chamber 210, and one or more mechanical flow modulators 254, which modulate the air flow and direct the air flow to different locations of the process chamber 210. In one embodiment, the system 200 includes one variable speed blower 252 that mounts on top of the process chamber 210 and directs the air flow to the upper window of the process chamber. In another embodiment, the system 200 includes two variable speed blowers 252 that mount on top and bottom of the process chamber and direct the air flow to the upper window and the lower window of the process chamber, respectively.

As action commands are executed by the actuators 250, process runs are continuingly performed by the process chamber 210, measurements are taken again by the sensors 220, and new process data are collected and then transmitted to digital twin model 230. The process described above is referred to as a closed-loop process or a feedback process. It includes collecting the process-run data at the process chamber 210, transmitting the data to the digital twin model 230, performing simulation and analysis of the data, generating insight, and determining actions.

FIGS. 3A and 3B illustrate methods 300, 301 for window temperature control, according to embodiments of the present disclosure. The methods 300, 301 may, for example, be performed by applications or algorithms described herein. The methods 300, 301 may be implemented using one or more computing systems, such as one or more processors and a non-transitory computer readable medium comprising instructions for performing techniques described herein. The method 300 and the method 301 only differ at operations 312 and 322, therefore, a discussion on the method 300 below also applies to the method 301.

The method 300 begins at operation 302, in which the sensors 220 take a single point temperature measurement at a certain location of the upper window 408 of the process chamber 210. The measurement is taken by one or more pyrometers 222 and represents a real-time temperature of the point-of-interest on the outer surface of the window. Additional measurements may also include a temperature of the lower window 410, a temperature of a substrate support 406, or a temperature of a substrate 402 as shown in and described with respect to FIG. 4.

At operation 304, the sensors 220 provide the measurement data to the digital twin model 230 as an input. The measurement data can be provided though a hardwired or wireless communication device. The measurement data can be provided to the digital twin model 230 via a middleware that stores, pre-processes, and transmits the measurement data as shown in FIG. 2.

At operation 306, the digital twin model 230 runs a simulation and analysis and synthesizes a temperature mapping of the entire inner surface of the window. The synthesized temperature mapping is received by the system 200 as an output from the digital twin model 230. This operation includes virtual sensing, in which new parameters are synthesized based on received measurement data. At least some of the synthesized parameters are different parameters from the parameters that were measured. For example, the digital twin model 230 may synthesize the temperature mapping of the inner surface of the window, which may not be directly measured by the one or more pyrometers, based on a single-point measurement on the outer surface of the window, as well as based on one or more known or estimated operational characteristics, such as temperature, pressure, flow rate, and the like.

At operation 308, the synthesized temperature mapping of the inner surface of the window is compared to a threshold temperature at a given region to determine if the simulated temperature exceed a desirable range. The comparison result provides an insight of a process run to be performed, such as potential failure or undesirable outcome, and thus recommending needed adjustments of the process conditions. Based on process knowledge, a higher priority or weight of can be assigned to regions with higher possibility of window coating, such as the region near the exhaust.

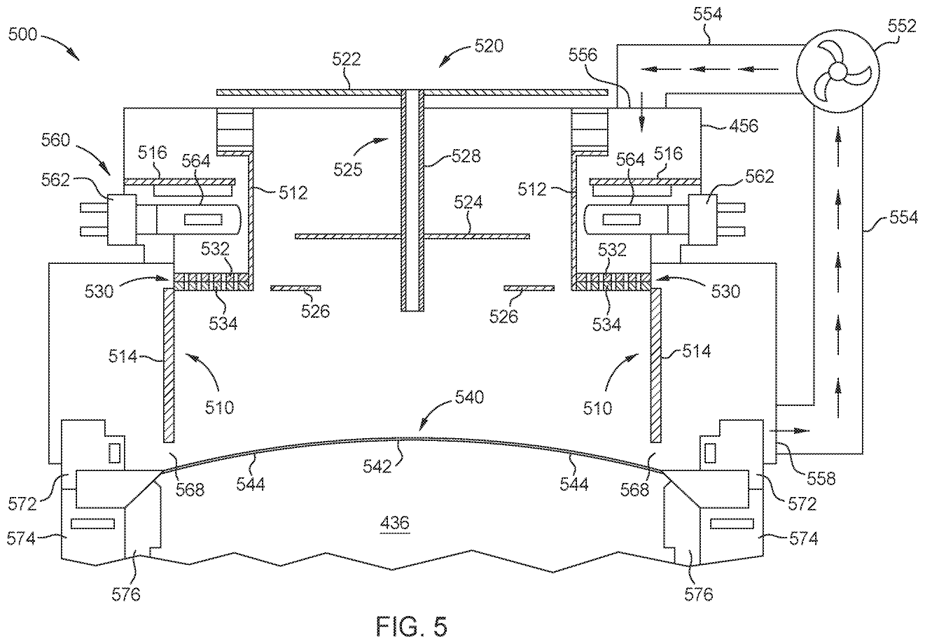

At operation 310, the insight 236 is then provided to the controller 240 for a decision. Depending on the nature and architecture of the controller 240, it may employ various algorithms, such as closed-loop, adaptive, intelligent, robust, or stochastic algorithms as mentioned previously. The controller 240, based on the insight 236, determines potential actions of actuators 250 to correct the temperature deviations. In some embodiments, the decision is to adjust the electric power supplied to the variable speed blowers 252, or to control a motor (not shown) coupled to the mechanical flow modulators 254 (details in FIGS. 5-7).

In one embodiment (FIG. 3A), at operation 312, the variable speed blowers 252 receive an action command from the controller 240. The action commend is to adjust the fan speed of the variable speed blowers 252 to increases, maintains, or lowers the flow rate of internal air flow circulation. An exemplary action tree may include the following:
i. Operation 312A: reduce VSB fan speed if a synthesized temperature at a given region T_{m,n} is lower than a low threshold T_{low} (T_{m,n}<T_{low});
ii. Operation 312B: maintain VSB fan speed if a synthesized temperature at a given region T_{m,n} is within the range of low threshold T_{low} and high threshold T_{high} (T_{low}<T_{m,n}<T_{high}); and
iii. Operation 312C: increase VSB fan speed if a synthesized temperature at a given region T_{m,n} is higher than a high threshold T_{high} (T_{m,n}>T_{high}).

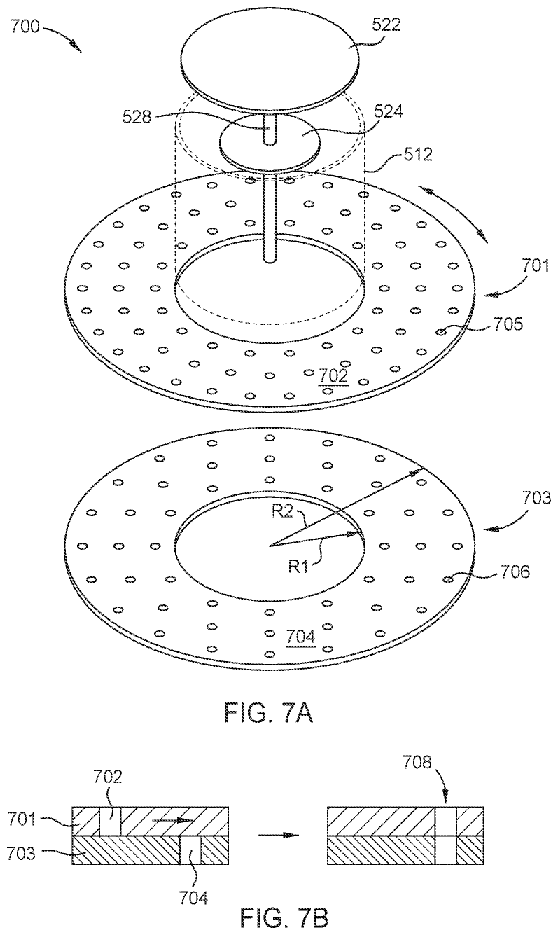

In another embodiment (FIG. 3B), at operation 322, the mechanical flow modulators 254 receive an action command from the controller 240. The action commend is to modulate the velocity and volume of air flows at different regions of the window. An exemplary action tree may include the following:
i. Operation 322A: vertically move a baffle structure 525 (FIG. 5) of a central flow modulator up and down to modulate the central air flow towards the central region of the window; and
ii. Operation 322B: adjust open area 708 (FIG. 7B) of a periphery flow modulator to modulate the periphery air flow towards the periphery region of the window.

In some embodiments, the control command can be an action to adjust both the variable speed blowers 252 and the mechanical flow modulators 254 for a rapid response. In some embodiments, an upper VSB fan, a lower VSB fan, a central flow modulator 520, and a periphery flow modulator 530 can be controlled separately.

At operation 314, a single point temperature measurement is retaken by sensors 220, such as one or more pyrometers 222, and sent back to the digital twin model 230 to close the feedback loop. The single point temperature measurement is to determine if the adjustment made in operations 312A, 312B, 312C, 322A, or 322B is able to reset the temperature at a point-of-interest to a desirable range. The feedback loop also generates a data flow to constantly calibrate the digital twin model 230. The calibration may be done during a process run cycle or after a chamber clean process before a next process run cycle starts.

### Exemplary Process Chamber

FIG. 4 is a schematic, cross-sectional, side view of a process chamber 400, according to one or more embodiments of the present disclosure. The process chamber 400 can be used as the process chamber 210 in FIGS. 2 and 3. In one or more embodiments, the process chamber 400 is an epitaxial deposition chamber. The process chamber 400 is utilized to grow an epitaxial film on a substrate 402. The process chamber 400 creates a cross-flow of precursors across a top surface 450 of the substrate 402. In one or more embodiments, the process chamber 400 is used for rapid thermal processing. The process chamber 400 can operate under vacuum, such as, at reduced pressures or near atmospheric pressure.

The process chamber 400 includes an upper housing 456, a lower housing 448 disposed below the upper housing 456, and a flow module 412 disposed between the upper housing 456 and the lower housing 448. The process chamber 400 further includes a chamber body 423 at least partially enclosing a substrate processing region 411. The chamber body 423 at least includes an upper window 408 and a lower window 410. A substrate support 406 is disposed within the chamber body between the upper window 408 and the lower window 410 to support the substrate 402. A plurality of upper heat sources 441 and a plurality of lower heat sources 443 are disposed between the process chamber 400 and the chamber body 423. As shown, a controller 420 is in communication with the process chamber 400 and is used to control processes and methods, such as the operations of the methods described herein.

In one or more embodiments, the heat sources (such as the upper heat sources 441 and/or lower heat sources 443) discussed herein include radiant heat sources such as lamps, for example halogen lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The plurality of upper heat sources 441 are disposed between the upper window 408 and a chamber ceiling 454. The plurality of upper heat sources 441 form a portion of an upper heat source module 455. Upper heat sources 441 provide heat to the substrate 402 and/or the substrate support 406. Upper heat sources 441 can be, for example, tungsten filament heat sources or higher power LEDs. The plurality of upper heat sources 441 can direct radiation, such as infrared radiation, through the upper window 408 to heat the substrate 402 and/or the substrate support 406. The chamber ceiling 454 may include a plurality of sensors disposed therein for measuring the temperature within the process chamber 400.

The plurality of lower heat sources 443 are disposed between the lower window 410 and a chamber floor 452. The plurality of lower heat sources 443 form a portion of a lower heat source module 445. Lower heat sources 443 can be, for example, tungsten filament heat sources or higher power LEDs. The plurality of lower heat sources 443 can direct radiation, such as infrared radiation, through the lower window 410 to heat the substrate 402 and/or the substrate support 406.

The upper heat sources 441 above the substrate support 406 can be installed adjacent to an upper shell assembly 490 and within or adjacent to an upper reflector 440. The upper reflector 440 can surround the perimeter of the upper shell assembly 490. Generally, the upper reflector 440 and/or the upper shell assembly 490 can be formed of a reflective metallic alloy, such as a reflective aluminum alloy. An upper temperature sensor 492, such as a pyrometer, can be installed in or adjacent to the upper shell assembly 490 to detect a temperature of the substrate 402 during processing. Alternatively, the upper temperature sensor 492 can be configured to detect the temperature of a particular point on the upper window 408 as described with respect to FIGS. 2 and 3.

The lower heat sources 443 can be installed within or adjacent to a lower reflector 430 and within or adjacent to a lower shell assembly 493. The lower reflector 430 can surround the lower shell assembly 493. Generally, the lower reflector 430 and/or the lower shell assembly 493 can be formed at least partially (such as partially or entirely) of a reflective metallic alloy, for example a reflective aluminum alloy. A lower temperature sensor 494, such as a pyrometer, can be installed in the lower shell assembly 493 to detect a temperature of the substrate support 406 or the back side of the substrate 402. Alternatively, the lower temperature sensor 494 can be configured to detect the temperature of a particular point on the lower window 410 as described with respect to FIGS. 2 and 3. One or both of the lower reflector 430 and/or the lower shell assembly 493 may be fabricated as later described below with reference to an upper shell assembly 490 and/or an upper reflector 440.

Although FIG. 4 shows the same size and number of heat sources 441, 443 installed above the upper window 408 and below the lower window 410 respectively, different types, intensity, wavelength, numbers, and/or sizes of heat sources may be installed within or adjacent to one or more of the reflectors 430, 440. Additionally, upper heat sources 441 and lower heat sources 443 may be disposed in additional and/or alternative locations.

The upper reflector 440, the lower reflector 430, the upper shell assembly 490, and the lower shell assembly 493 (and/or other component(s) including the metallic alloy) can be manufactured by processes such as, but not limited to, melt spinning, or any other process including rapid liquid quenching, gaseous quenching, and/or rate-controlled chemical and solid reactions. One or more surfaces of the metallic alloy can further be smoothened for increased surface reflectivity. In one or more embodiments, the metallic alloy is an aluminum alloy. In one or more embodiments, the metallic alloy is a brass alloy that includes copper and zinc. In one or more embodiments, the metallic alloy includes a post-transition metal (such as aluminum) and one or more transition metals (such as one or more of iron, nickel, copper, manganese, molybdenum, and/or zirconium). The metallic alloy has an alloy composition that includes a post-transition atomic percentage (such as an aluminum atomic percentage) that is at least 80% and a transition atomic percentage of the one or more transition metals that is at least 5%. In one or more embodiments, a sum of the post transition atomic percentage and the transition atomic percentage is at least 95%.

The upper window 408 and the lower window 410 are formed of an IR energy transmissive material, such as quartz, and may be transparent in various embodiments, to allow IR energy to pass from the upper heat sources 441 and lower heat sources 443 to the substrate 402 and/or the substrate support 406.

A processing volume 436 and a purge volume 438 are formed between the upper window 408 and the lower window 410. The processing volume 436 and the purge volume 438 are part of a processing region 411 defined at least partially by the upper window 408, the lower window 410, one or more upper liners 422, and one or more lower liners 409.

The processing region 411 has the substrate support 406 disposed therein. The substrate support 406 includes a top surface on which the substrate 402 is disposed. The substrate support 406 is attached to a shaft 418. The shaft 418 is connected to a motion assembly 421. The motion assembly 421 includes one or more actuators and/or adjustment devices that provide movement and/or adjustment for the shaft 418 and/or the substrate support 406 within the processing region 411.

The substrate support 406 may include lift pin holes 407 disposed therein. The lift pin holes 407 are sized to accommodate lift pins 432 for lowering and lifting of the substrate 402 to and from the substrate support 406 before or and a deposition process is performed. The lift pins 432 may rest on lift pin stops 434 when the substrate support 406 is lowered from a process position to a transfer position. The lift pin stops 434 can be coupled to a second shaft 404 through a plurality of arms.

The flow module 412 includes a plurality of gas inlets 414, a plurality of purge gas inlets 464, and one or more gas exhaust outlets 416. In one or more embodiments, the plurality of gas inlets 414 and the plurality of purge gas inlets 464 are disposed on the opposite side of the flow module 412 from the one or more gas exhaust outlets 416. The upper liners 422 and the lower liners 409 are disposed on an inner surface of the flow module 412 and protect the flow module 412 from reactive gases used during deposition operations and/or cleaning operations. The gas inlet(s) 414 and the purge gas inlet(s) 464 are each positioned to flow a gas parallel to the top surface 450 of a substrate 402 disposed within the processing region 411. The gas inlet(s) 414 are fluidly connected to one or more process gas sources 451 and one or more cleaning gas sources 453. The purge gas inlet(s) 464 are fluidly connected to one or more purge gas sources 462. The one or more gas exhaust outlets 416 are fluidly connected to an exhaust pump 457. One or more process gases supplied using the one or more process gas sources 451 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), hydrogen (H₂), and/or nitrogen (N₂)). One or more cleaning gases supplied using the one or more cleaning gas sources 453 can include one or more of hydrogen (H) and/or chlorine (CI). In one or more embodiments, the one or more process gases include silicon phosphide (SiP) and/or phospine (PH₃), and the one or more cleaning gases include hydrochloric acid (HCl).

The one or more gas exhaust outlets 416 are further connected to or include an exhaust system 478. The exhaust system 478 fluidly connects the one or more gas exhaust outlets 416 and the exhaust pump 457. The exhaust system 478 can assist in the controlled deposition of a layer on the substrate 402. In one or more embodiments, the exhaust system 478 is disposed on an opposite side of the process chamber 400 relative to the gas inlet(s) 414 and/or the purge gas inlet(s) 464.

A pre-heat ring 446 is disposed outwardly of the substrate support 406. The pre-heat ring 446 is supported on a ledge of the one or more lower liners 409. In one or more embodiments, the pre-heat ring 446, the lower liners 409, and the upper liners 422 are formed of one or more of quartz (such as transparent quartz, e.g. clear quartz; opaque quartz, e.g., white or grey quartz; and/or black quartz), silicon carbide (SiC), and/or graphite coated with SiC.

During processing, one or more process gases P1 flow from the gas inlet(s) 414, into the processing region 411, and over the substrate 402 to form (e.g., epitaxially grow) one or more layers on the substrate 402 while the heat sources 441, 443 heat the substrate 402. After flowing over the substrate 402, the one or more process gases P1 flow out of the processing region through the one or more gas exhaust outlets 416. The flow module 412 can be at least part of a sidewall of the process chamber 400. Embodiments of the present disclosure also contemplate that one or more purge gases can be supplied to the purge volume 438 (through the plurality of purge gas inlets 464) during the deposition operation, and exhausted from the purge volume 438.

As shown, a controller 420 is in communication with the process chamber 400 and is used to control processes and methods, such as the operations of the methods described herein. The controller 420 is configured to receive data or input as sensor readings from a plurality of sensors. The controller 420 is equipped with or in communication with the digital twin model 230 of the process chamber 400. The digital twin model 230 includes a heating model, a rotational position model, and/or a gas flow model. The digital twin model 230 includes a program configured to estimate parameters (such as a gas flow rate, a gas pressure, a processing temperature, a rotational position of component(s), a heating profile, and/or a cleaning condition) within the process chamber 400 throughout a deposition operation and/or a cleaning operation. The controller 420 is further configured to store readings and calculations. The readings and calculations include previous sensor readings, such as any previous sensor readings within the process chamber 400. The readings and calculations further include the stored calculated values from after the sensor readings are measured by the controller 420 and run through the digital twin model 230. Therefore, the controller 420 is configured to both retrieve stored readings and calculations as well as save readings and calculations for future use. Maintaining previous readings and calculations enables the controller 420 to adjust the digital twin model 230 over time to reflect a more accurate version of the process chamber 400.

The controller 420 can monitor, estimate an optimized parameter, adjust a first gas flow rate (process gas) inside the processing region 411, adjust a second gas flow rate (conditioning gas) outside the upper/lower window, initiate a reflector cooling operation, generate an alert on a display, halt a deposition operation, initiate a chamber downtime period, delay a subsequent iteration of the deposition operation, initiate a cleaning operation, halt the cleaning operation, adjust a heating power, and/or otherwise adjust the process recipe.

The controller 420 includes a central processing unit (CPU) 424 (e.g., a processor), a memory 426 containing instructions, and support circuits 428 for the CPU 424. The controller 420 controls various items directly, or via other computers and/or controllers. In one or more embodiments, the controller 420 is communicatively coupled to dedicated controllers, and the controller 420 functions as a central controller.

The controller 420 is of any form of a general-purpose computer processor that is used in an industrial setting for controlling various substrate process chambers and equipment, and sub-processors thereon or therein. The memory 426, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 428 of the controller 420 are coupled to the CPU 424 for supporting the CPU 424. The support circuits 428 include cache, power supplies, clock circuits, input/output circuitry and subsystems, and the like. Operational parameters and operations are stored in the memory 426 as a software routine that is executed or invoked to turn the controller 420 into a specific purpose controller to control the operations of the various chambers/modules described herein. The controller 420 is configured to conduct any of the operations described herein. The instructions stored on the memory, when executed, cause one or more of operations of the method 300 (described previously) to be conducted in relation to the process chamber 400. The controller 420 and the process chamber 400 are at least part of a system for processing substrates.

### Chamber Conditioning Assembly

FIG. 5 is a schematic, cross-sectional, side view of a chamber conditioning assembly. The chamber conditioning assembly 500 refers to the upper portion of the process chamber 400 above the upper window 408, as shown in FIG. 4. In some embodiments, the chamber conditioning assembly 500 may also include the lower portion of the process chamber 400 below the lower window 410, as shown in FIG. 4. In one or more embodiments, the chamber conditioning assembly 500 comprises a heat source module 560 comprising a plurality of heat sources 564, a reflector assembly 510 comprising a plurality of reflectors, one or more variable speed blowers 552, a central flow modulator 520, and a periphery flow modulator 530. The chamber conditioning assembly 500 is configured to provide rapid heating and cooling capacities to control the temperatures of an upper window 540 (e.g., the upper window 408 in FIG. 4) and a lower window (e.g., the lower window 410 in FIG. 4) (not shown) and the processing region 411 enclosed between the upper and lower windows.

To differentiate with the chamber conditioning assembly 500, the process chamber in the discussion forward refers to the upper window 540 and the processing region 411 under the upper window 540. The processing region 411 is sealed by an upper clamp ring 572, a base ring 574, and an upper chamber liner 576.

The plurality of heat sources 564 are radially disposed around the chamber conditioning assembly 500 and configured to provide thermal radiation to the processing region 411. Detailed description of the heat sources 564 is provided in the previous section.

The reflector assembly 510 includes a cylindrical inner reflector 512, a cylindrical outer reflector 514, and an annular top reflector 516. The plurality of reflectors are disposed around the heat sources 564 to redirect the thermal radiation and to focus the thermal energy towards the processing region 411. The plurality of reflectors are configured in a way that the reflected radiation is able to cover the entire surface of the window.

The variable speed blower 552 provides an air flow via a conduit 554, directed through the upper housing 456. More specifically, the air flow is supplied via the conduit 554 to the upper housing 456 through an inlet port 556. The air flow may exit the upper housing 456 via an exhaust port 558. In some embodiments, the gas used to condition the chamber may be any convenient gas, such as ambient or clean dry air. In other embodiments, the gas is typically selected to be chemically inert in the environment adjacent to the upper window 540 outside the processing volume. Examples of gases that may be used include nitrogen, helium, argon, and combinations thereof.

The central flow modulator 520 comprises coaxially disposed upper baffle 522, middle baffle 524, and lower baffle 526, collectively working together to direct the central air flow towards the central region of the window. The upper baffle 522 and the middle baffle 524 are fixedly attached to a cylindrical sensor tube 528 to form a monolithic baffle structure 525. The baffle structure 525 is placed inside the cylindrical inner reflector 512.

The periphery flow modulator 530 comprises a stack of perforated plates, including at least a first plate 532 and a second plate 534, rotatable with respect to each other, configured to align or misalign perforation patterns within the stack of perforated plates, to increase or reduce open area. The periphery flow modulator 530 is made of highly transparent materials, such as clear fused quartz, allowing more than 95% IR transmission through the materials. The periphery flow modulator 530 is disposed under the heat sources 564 to modulate air flow through a plurality of heat source sockets 562, configured to house the plurality of heat sources 564.

### Central Flow Modulator

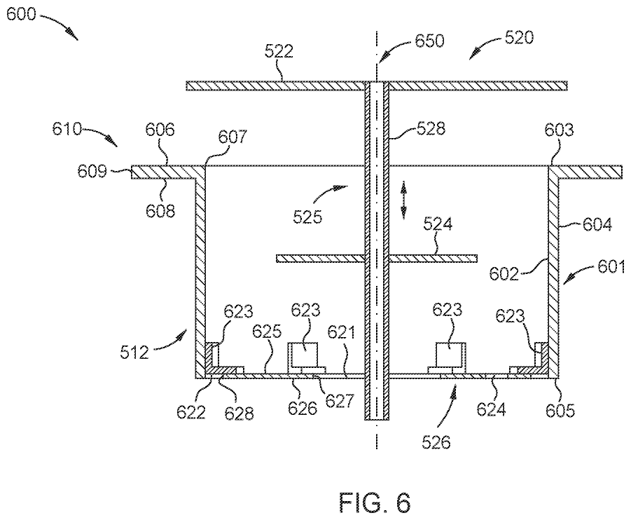

FIG. 6 is a detailed side view of the central flow modulator 520, according to embodiments of the present disclosure.

The central flow modulator 520 includes the inner reflector 512, the baffle structure 525, and the lower baffle 526. The inner reflector 512 includes a shell body 601, and a shell flange 610. The shell body 601 has a cylindrical shape with an inner diameter surface 602, and an outer diameter surface 604, a proximal end 603, and a distal end 605. The shell flange 610 has an upper surface 606, a lower surface 608, an inner diameter edge 607, and an outer diameter edge 609 that extends radially outward from the inner diameter surface 602 of the shell body 601. The shell flange 610 is connected to the proximal end 603 of the shell body 601 at the inner diameter edge 607 as a one piece monolithic structure.

The baffle structure 525 includes the upper baffle 522, the middle baffle 524, and the cylindrical sensor tube 528. The upper baffle 522 and the middle baffle 524 are annular plates coaxially disposed around a central axis 650 of the cylindrical sensor tube 528 to form a monolithic structure. The baffle structure 525 may be constructed of the same material as the upper reflector 516, or other suitable material, such as the metallic alloy discussed herein, and may be polished and/or coated similarly.

The lower baffle 526 is located at the distal end 605 of the shell body 601. In some embodiments, the lower baffle 526 may be an annular plate having a top surface 625 and bottom surface 626, respectively, with an inner edge 627 and an outer edge 628. The lower baffle 526 may be a separate component connected to the inner diameter surface 602 of the shell body 601, or be connected to the distal end 605 of the shell body 601 as a one piece monolithic structure.

The top surface 625 of the lower baffle 526 may be connected to the inner diameter surface 602 by connectors 623 in a manner that creates an annular gap 622 between the inner diameter surface 602 and the outer edge 628. The connector 623 may be a bracket or structure suitable for connecting the lower baffle 526 to the shell body 601. In one or more embodiments, the connectors 623 are a web of material extending between the outer edge 628 of the lower baffle 526 and the inner diameter surface 602 at the distal end 605 of the shell body 601 when the shell body 601 and lower baffle 526 are fabricated as a monolithic structure. The lower baffle 526 may be constructed of the same material as the upper reflector 516 and polished and/or coated similarly. Furthermore, the lower baffle 526 may have a cut out 624 that enables a second temperature sensor, for example a pyrometer, to have a line of sight down to the edge of the substrate 402. The cylindrical sensor tube 528 is generally utilized to provide a line of sight for a first temperature sensor, for example the upper temperature sensor 492 shown in FIG. 4, down to the center of the substrate 402.

The central flow modulator 520 is configured to modulate the air flow. The air flow from the variable speed blower 552 is directed into the volume inside the inner reflector 512, and modulated by the upper baffle 522, middle baffle 524, and lower baffle 526 along the air flow path. The modulated air converges at the central opening 621 of the lower baffle 526, and is directed to a central region 542 of the upper window 540. The central air flow carries out the heat from the central region 542 and exits through an air exhaust opening 568 around the edge of the upper window 540 (FIG. 5).

### Periphery Flow Modulator

FIG. 7A is a schematic isometric view of a periphery flow modulator 700, according to embodiments of the present disclosure. The periphery flow modulator 700 comprises a stack of coaxial, rotatable, perforated plates. The stack of plates include at least a first perforated plate 701 and a second perforated plate 703, each having a central opening and a plurality of perforations 705, 706. In some embodiments, the perforated plates 701, 703 are annular plates with certain thickness, i.e., a flat disc with a circular central cutout. The annular plates have an inner diameter R1 and an outer diameter R2. Other geometric shapes may also be employed to the design. In some embodiments, the perforated plates 701, 703 are made of transparent materials, such as clear fused quartz, so that IR energy can pass through. In some embodiments, the stack of plates may include more than two perforated plates, such as three perforated plates.

In one embodiment as shown in FIG. 7A, the first perforated plate 701 has a first perforation pattern 702 comprising a first plurality of perforations 705, and the second perforated plate 703 has a second perforation pattern 704 comprising a second plurality of perforations 706. The perforated plates 701, 703 may have versatile perforations, such as round, square, slot and hexagon perforations, or perforations of any other geometric shapes. The plurality of perforations 705, 706 may be arranged in straight or staggered rows, such as 60° staggered or 45° staggered. In addition, the plurality of perforations 705, 706 may be densely packed, loosely packed, or randomly distributed.

The first perforated plate 701 is placed adjacent to the second perforated plate 703, and rotates with respect to the second perforated plate 703, so that the perforation patterns of the first perforated plate 701 and the second perforated plate 703 are aligned to allow air flow through or misaligned to block the air flow. The rotation operation increases or reduces open area 708 and subsequently adjusts the velocity and speed of the air flow. The open area 708 is a ratio that reflects how much of the perforated plate is occupied by perforations, normally expressed by percent. For example, if the open area of the perforated plate is 30%, it means that 30% of the perforated plate is perforations and 70% of the perforated plate is material. In some embodiments, the rotation of the perforated plates 701, 703 are controlled by an electric motor (not shown).

In one embodiment, the first perforation pattern 702 may be the same as the second perforation pattern 704. In another embodiment, the first perforation pattern 702 may be different than the second perforation pattern 704. In some embodiments, one plate can have the same or alternating perforation sizes. The diameter of the perforations may range from 5 mm to 5 cm. The perforation patterns may be symmetric or asymmetric depending on the temperature modulation requirements in different processes. The number, size and location of perforations in the perforated plates are purposely designed for optimum results.

FIG. 7B illustrates relative alignments of the perforated plates 701, 703. In a first alignment position, the first perforation pattern 702 of the first perforated plate 701 is misaligned with the second perforation pattern 704 of the second perforated plate 703, so the air flow is blocked by the double plates. In a second alignment position, by rotating the first perforated plate 701 with respect to the second perforated plate 703 for a certain angle, the first perforation pattern 702 of the first perforated plate 701 is aligned with the second perforation pattern 704 of the second perforated plate 703, so the air flow can pass through the double plates. Air flow rate is thus modulated by rotating or orienting one plate versus the other plate. In one configuration, one plate is stationary and one plate is rotatable. In another configuration, both plates are rotatable. The double plates may be controlled by an electric motor (not shown). At one rotation angle, more perforations are aligned between two plates allowing a greater open area and thus a greater air flow; at another rotation angle, less perforations are aligned between two plates allowing a less open area and thus a less air flow. Different alignment positions may also allow the air flow through the inner, middle, outer rings of the plates along the radius. Thus, a more controlled temperature modulating is achieved at the central, middle, and edge of the window with respect to the central axis of the window.

In an exemplary configuration, a first set of openings is opened up at the central region of the window by rotating one plate for 60°, and a second set of openings is opened up at the periphery region of the window by rotating one plate for 120°. The rotation angle of the plate could be determined by the operational state of the physical chamber (e.g., process chamber 210) and the corresponding digital twin (e.g., digital twin model 230). For example, during clean process, the air flow can be directed more towards the edge of the window, so the central region can heat up more to make the clean process more effective. In contrast, during deposition, the air flow can be directed more towards the regions with higher probability of window coating based on the digital twin model.

### Dynamics of the Chamber Conditioning Assembly

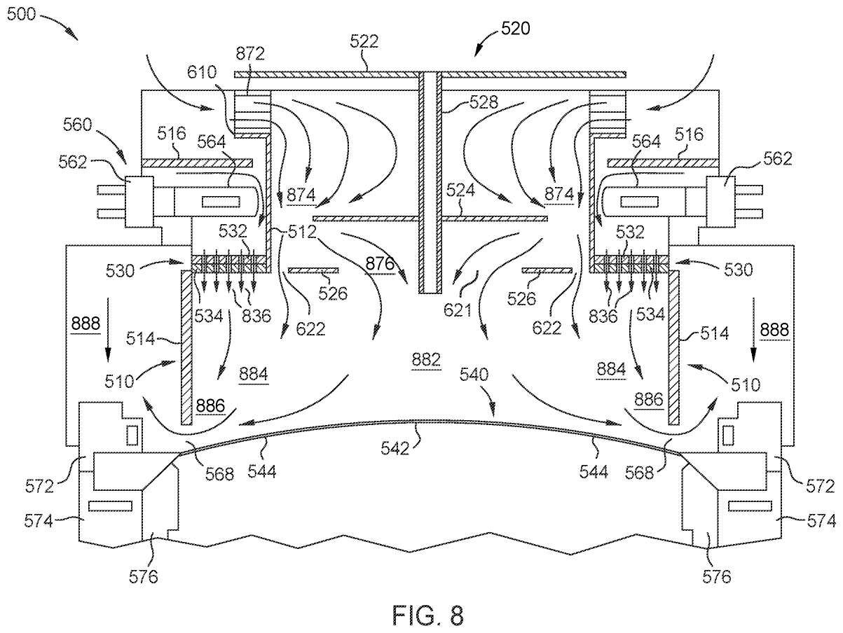

FIG. 8 illustrates air flow distribution in the chamber conditioning assembly 500 when the system is in operation. The arrows and lines in the figure illustrate the air flow at different locations of the assembly 500.

In one or more embodiments, at least one variable speed blower 552 (FIG. 5) is coupled to the chamber conditioning assembly 500. The variable speed blower 552 provides an air flow via the conduit 554 (FIG. 5), directed through the assembly 500. More specifically, the air flow enters the assembly 500 via the inlet port 556 and is directed to the upper window 540 by one or more air flow modulators. The air flow then travels along the top surface of the upper window 540 and exits the assembly 500 via the exhaust port 558. The air flow carries away the excessive heat of the upper window 540 and adjusts the temperature of the upper window 540.

In one or more embodiments, the variable speed blower (VSB) 552 may form multiple air flow streams entering into the assembly 500. A first air flow stream, also referred as central air flow 882, enters into the chamber through the central flow modulator 520 as discussed in above sections, more specifically, through the gap between the inner reflector 512, the baffle structure 525, and the central opening of the lower baffle 526. Central air flow 882 first passes through the entrance portion 872 of the central flow modulator 520, formed by upper baffle 522 and shell flange 610, then through the middle portion 874 of the central flow modulator 520, formed by middle baffle 524 and shell body 601, and finally merges through the exit portion 876 of the central flow modulator 520, formed by the central opening 621 of the lower baffle 526. The central flow modulator 520 directs the air flow towards the central region 542 of the upper window 540, modulating the window temperature of the central region 542. Based on the simulation result, changing the diameters and/or the relative positions of the upper baffle 522, the middle baffle 524, and the lower baffle 526 will increase or decrease the gaps of the entrance portion 872, the middle portion 874, and the exit portions 876 of the central modulator 600, and subsequently modulate the air flow through these gaps. In one embodiment, the baffle structure 525 is motorized (motor not shown) and is configured to move up and down vertically along the central axis 650 with respect to the inner reflector shell. The vertical movement of the baffle structure 525 adjusts the volume and speed of central air flow.

A second air flow stream, also referred as periphery air flow 884, flows through a plurality of heat source sockets 562 behind a plurality of heat sources 564, and enters into the chamber though the periphery flow modulator 530 comprising a stack of perforated plates. The heat source socket 562 is a housing structure to host the heat source 564, such as a heating lamp. The plurality of heat source sockets 562 and heat sources 564 are axisymmetrically arranged around the cylindrical inner reflector 512, adjacent to inner reflector shell. The heat source socket 562 connects the inside and the outside of the reflector assembly 510, allowing air steam to flow from the outside to the inside of the reflector assembly 510. The air flow stream is confined between inner reflector shell and the outer reflector shell, guided towards the periphery flow modulator 530 positioned between the inner reflector 512 and outer reflector 514, and passes through the openings of the periphery flow modulator 530. This air steam merges with a small air stream flowing through annular gap 622 between the inner diameter surface 602 and the outer edge 628 (shown in FIG. 6) and forms the periphery air flow 884, flowing towards a periphery region 544 of the upper window 540. The inner diameter of the periphery flow modulator 530 (radius of the central opening, R1 in FIG. 7A) may match with the outer diameter of the inner reflector 512, and the outer diameter of the periphery flow modulator 530 (radius of the double plates, R2 in FIG. 7A) may match with the inner diameter of outer reflector 514. The central air flow 882 and periphery air flow 884 converge at the periphery region 544 of the upper window 540 to form an exhaust air flow 886 and exit the reflector assembly 510 through an air exhaust opening 568.

In some embodiments, there may be a third air flow stream 888, separated from the first and second air flow streams, that flows outside the reflector assembly 510, between the outer reflector shell and the inner wall of the upper housing. The third air flow stream 888 is modulated by at least one mechanical flow modulator along its air flow path, and is directed to the upper clamp ring 572 and seals around the edge of the window. The third air flow stream 888 helps secure the integrity of the O-rings and seal materials that maintain a vacuum in the processing volume.

The first, second, and third air flows transfer the heat from the window to an air-liquid heat exchanger (not shown), for example, to facility cooling water. Cooled air is returned to the variable speed blower (VSB) forming a closed-loop air circulation.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a chamber body at least partially enclosing a substrate processing region;
a pyrometer to take a temperature measurement of a first location of the chamber body;
a controller configured to:
estimate temperature at one or more second locations of the chamber body based on the temperature measurement at the first location; and
adjust an operation of the substrate processing system based on the estimated temperature at the one or more second locations.

2. The substrate processing system of claim 1, wherein a digital twin model is designed to emulate components and processes of the chamber body, the digital twin model configured to:
receive an input from the pyrometer;
conduct a virtual processing based on the received input; and
generate an output indicative of a temperature mapping within the chamber body.

3. The substrate processing system of claim 2, wherein the digital twin model is a physics-based model, a data-based model, or a hybrid model that incorporates both physics-based and data-based modeling approaches.

4. The substrate processing system of claim 2, wherein the digital twin model uses real-time operational data to calibrate predictive models of processing conditions in the chamber body.

5. The substrate processing system of claim 1, wherein the chamber body comprises at least an upper window and a lower window made of transparent materials allowing more than 95% IR transmission.

6. The substrate processing system of claim 5, wherein the upper window and the lower window comprise an upper portion and a lower portion of a monolithic frameless box that is made entirely from transparent materials.

7. The substrate processing system of claim 5, wherein a temperature is measured from at least one of an outer surface of the upper window or an outer surface of the lower window.

8. The substrate processing system of claim 1, further comprising a chamber conditioning assembly disposed outside the chamber body to modulate processing conditions inside the chamber body.

9. The substrate processing system of claim 8, wherein the chamber conditioning assembly comprising:
one or more variable speed blowers configured to generate an air flow outside the chamber body; and
one or more mechanical flow modulators configured to modulate the air flow and direct the air flow towards a central region and a periphery region of the chamber body.

10. A method for operating a substrate processing chamber, the method comprising:
taking a temperature measurement at a first location of a chamber body that at least partially encloses a substrate processing region;
estimating temperature at one or more second locations of the chamber body based on the temperature measurement; and
adjusting an operation of the substrate processing chamber based on the estimated temperature at the one or more second locations.

11. The method of claim 10, further comprising:
taking a second temperature measurement of the chamber body after a process run and calibrating a digital twin model of the substrate processing chamber based on the second temperature measurement.

12. The method of claim 10, wherein the temperature of the chamber body is adjusted by modulating fan speeds of one or more variable speed blowers or controlling one or more mechanical flow modulators.

13. A chamber conditioning assembly, comprising:
one or more variable speed blowers configured to supply an air flow to a chamber body comprising an upper window and a lower window;
a first mechanical flow modulator comprising a baffle structure, configured to direct a first air flow stream towards a central region of the chamber body; and
a second mechanical flow modulator comprising a plurality of perforated plates configured to direct a second air flow stream towards a periphery region of the chamber body.

14. The chamber conditioning assembly of claim 13, wherein the first and second air flow streams move across outer surface of at least one of the upper window and the lower window.

15. The chamber conditioning assembly of claim 13, wherein the baffle structure of the first mechanical flow modulator comprising at least an upper baffle and a middle baffle coaxially disposed around a central axis, the baffle structure moving up and down to modulate the first air flow stream.

16. The chamber conditioning assembly of claim 13, wherein the plurality of perforated plates rotate with respect to each other to increase or reduce open area of the second mechanical flow modulator, modulating the second air flow stream.

17. The chamber conditioning assembly of claim 16, wherein the second air flow stream flows through a plurality of heat source sockets behind a plurality of heat sources before being guided by the second mechanical flow modulator.

18. The chamber conditioning assembly of claim 13, wherein an exhaust air flow formed by converging the first air flow stream and the second air flow stream at an edge of at least one of the upper window and the lower window, exiting the chamber conditioning assembly through an air exhaust opening.

19. The chamber conditioning assembly of claim 13, wherein a third air flow stream modulated by at least one mechanical flow modulator, flowing outside the chamber conditioning assembly, directed to clamp rings and seals around the upper window and the lower window.

20. The chamber conditioning assembly of claim 13, wherein the first, second, and third air flow streams transfer heat from the upper window and the lower window to an air-liquid heat exchanger, with cooled air returned to the one or more variable speed blowers to form a closed-loop air circulation.
